(19) United States
(12) Patent Application Publication
(10) Pub. No.: US 2003/0044697 A1
(43) Pub. Date: Mar. 6, 2003

(54) Methods and apparatus for correcting the proximity effect in a charged-particle-beam microlithography system and devices manufactured from the same

(75) Inventor: Sumito Shimizu, Yokohama (JP)

Correspondence Address: KLARQUIST SPARKMAN, LLP, One World Trade Center, Suite 1600, 121 S.W. Salmon Street, Portland, OR, 97204-2988, US

(73) Assignee: Nikon Corporation

(21) Appl. No.: 10/231,587

(22) Filed: Aug. 29, 2002

(30) Foreign Application Priority Data
Aug. 31, 2001 (JP) 2001-263181

(51) Int. Cl. G03F 9/00; G03C 5/00

(52) U.S. Cl. 430/5; 430/30; 430/296; 430/942

(57) ABSTRACT

Methods and apparatus for correcting the proximity effect in a charged-particle-beam (CPB) microlithography system are disclosed. The disclosed methods involve adjusting the exposure dose and performing local resizing on pattern elements defined on a reticle in order to eliminate pattern distortions caused by the proximity effect. In a first embodiment, the exposure dose is adjusted so that a first pattern element situated at a location on the reticle exhibiting greater-than-average (or having the greatest) distortion due to the proximity effect has a desired line-width. Other pattern elements defined on the reticle are then enlarged so that they produce resist images having desired respective line-widths. In a second embodiment, the exposure dose is adjusted so that a first pattern element situated at a location on the reticle exhibiting nearly average (or average) distortion due to the proximity effect has a desired line-width. Other pattern elements defined on the reticle are then enlarged or narrowed so that they produce resist images having desired respective line-widths.

### FIELD

This disclosure pertains to microlithography (transfer-exposure of a pattern to a sensitive substrate). Microlithography is a key technology used in the fabrication of microelectronic devices such as integrated circuits, displays, and micromachines. More specifically, this disclosure relates to charged-particle-beam (CPB) microlithography and to methods for reducing proximity effects that may distort the transferred pattern.

### BACKGROUND

Recently, there has been considerable effort in developing a practical microlithography technology that can form pattern elements having line-widths of 0.1 μm (100 nm) or smaller. To achieve such small feature sizes, microlithography apparatus utilizing a charged particle beam as the lithographic energy beam have been developed. In particular, CPB-microlithography apparatus utilizing an electron beam have been developed that exhibit sufficiently high throughput to handle the mass production of devices having line-widths of 0.1 μm and smaller.

One important feature of the electron-beam microlithography apparatus is the acceleration voltage of the electron beam, which may be as high as 100 kV. This high acceleration voltage is useful in forming pattern elements having small line-widths. As the electrons of the electron beam strike the large molecules that compose the resist, however, the electrons are scattered, and the trajectory of the electrons passing through the resist gradually widens. This phenomenon is known as “forward scattering.” With an increase in the acceleration voltage of the electron beam, however, the forward-scattering diameter decreases, allowing finer patterns to be formed. The electrons of the electron beam also are scattered by atoms of the substrate underlying the resist. The electrons may be scattered repeatedly by the atoms of the substrate until the energy of the electrons decreases to near zero. In contrast to scattering caused by the resist, however, the degree and extent of electron scattering caused by the substrate increases with corresponding increases in the acceleration voltage of the electron beam. For example, the lateral extent of electron scattering for an electron beam having an acceleration voltage of 100 kV is about 50 μm. A certain percentage of electrons entering the substrate are scattered back to the substrate surface and into the resist, where the electrons cause a partial “exposure” of the resist. These “backscattered” electrons cause undesirable variations in the exposure dose received by the resist, especially in adjacent pattern elements imprinted in the resist. This variable exposure phenomenon is termed the “proximity effect” and may cause a distorted image to be formed on the resist. Accordingly, correction of the proximity effect is an important aspect of achieving practical CPB microlithography.

Conventional methods for reducing the proximity effect generally involve making localized exposure doses closer to the desired respective doses. For example, certain methods involve changing and adjusting localized exposure doses by changing the beam intensity (“dose modulation”). The exposure area of a CPB-microlithography apparatus, however, is typically too large (e.g., 0.25 mm×0.25 mm) for this technique to be practical. Other methods involve changing the profiles of pattern elements as defined on the reticle (“local resizing” or “pattern biasing”). In a technique termed “negative local resizing,” the line-widths of pattern elements as defined on the reticle are narrowed deliberately to correct for the proximity effect and to restore the image formed on the resist (the “resist image”) to its desired line-width. For example, in a pattern containing equally spaced lines disposed along a length of 100 μm (e.g., a DRAM memory-gate pattern), the line-width of the central pattern elements on the reticle may be narrowed so that the images formed on the resist have the desired line-width.

FIGS. 6(A)-6(B) illustrate the conventional method of negative local resizing in order to correct for the proximity effect. In general, negative local resizing is performed by adjusting the exposure dose such that areas of the reticle exhibiting little or no distortion (when projected onto the substrate) caused by the proximity effect have the desired line-width, and narrowing the other pattern elements of the reticle that exhibit distortion. In FIG. 6(A), for instance, a stencil-type reticle 10 defines multiple apertures 10a-10i corresponding to various respective elements of the pattern. The apertures 10a-10g correspond to pattern elements in a dense line-and-space (L&S) pattern group, whereas the apertures 10h, 10i correspond to pattern elements separated from one another by relatively wide solid regions 10j, 10k. In FIG. 6(A), the widths of the apertures 10a-10i are identical. In a wafer 23 located downstream of the reticle 10, negative resist images 23a-23i are formed after exposure to an electron beam shaped by the respective apertures 10a-10i. Spaces 23j, 23k are formed downstream of the solid regions 10j, 10k.

In the illustrated example (FIG. 6(A)), the resist images 23a, 23g, which are formed by the electron beam passing through the apertures 10a, 10g, respectively, and which are located at the ends of the L&S-pattern group 23a-23g, have the desired line-width. Additionally, the resist images 23h, 23i, which are formed by the apertures 10h, 10i, respectively, and which are located in an area of the resist having a low pattern-element density, have the desired line-width. By contrast, the resist image 23d, which is located in the center of the L&S-pattern group 23a-23g, is wider than the desired line-width because of the proximity effect.

The variation in line-width caused by the proximity effect is illustrated with reference to FIG. 7. The data shown in FIG. 7 were generated by exposing a 250 μm×100 μm region of a reticle using an electron beam having an acceleration voltage of 100 kV. The L&S pattern formed on the resist had a line-to-space ratio of 1:1 and a desired line-width of 100 nm. The horizontal axis of FIG. 7 represents exposure position relative to the 250-μm dimension of the reticle. The vertical axis of FIG. 7 represents the line-width of the corresponding image on the resist, formed by the respective element at the designated position on the reticle. As shown in FIG. 7, the line-width of the resist images formed by pattern elements located at the edges of the 250-μm reticle is about 100 nm. With elements located near the center of the reticle, however, the line-width of the respective resist images is about 140 nm. Thus, local resizing of the pattern elements in the center of the L&S-pattern group is necessary to make the line-widths of the resist images uniform.

Referring now to FIG. 6(B), a stencil-type reticle 10′ is shown defining multiple corrected apertures 10′a-10′i that have been locally resized in order to correct for the proximity effect. In FIG. 6(B), a group of apertures 10′a-10′g corresponds to pattern elements in a dense L&S-pattern group, and the apertures 10′h, 10′i correspond to pattern elements separated from one another by wide solid regions 10′j, 10′k. The width of the corrected apertures 10′a, 10′g is nearly the same as of the respective uncorrected apertures 10a, 10g shown in FIG. 6(A). In other words, almost no local resizing was performed on the apertures 10a, 10g in FIG. 6(A) to form the respective apertures 10′a, 10′g in FIG. 6(B). By contrast, the corrected aperture 110′d, located in the center of the L&S-pattern group 23′a-23′g, is narrower than the respective uncorrected aperture 10d by an amount necessary to correct for the proximity effect. It is understood that the degree of narrowing shown in FIG. 6(B) is for illustrative purposes only and may not reflect the actual degree of local resizing necessary.

On a wafer 23′ located downstream of the reticle 10′, negative resist images 23′a-23′i are formed by exposure to an electron beam shaped by the apertures 10′a-10′i. Spaces 23′j, 23′k are formed downstream of the solid regions 10′j, 10′k. As shown in FIG. 6(B), the corrected apertures 10′a-10′i allow all the respective resist images 23′a-23′i to have the desired line-width. Accordingly, the negative local resizing method is used to reshape apertures located in areas of the reticle that experience large amounts of distortion due to the proximity effect when projected onto the resist.

FIG. 8 is a graph illustrating the amount of local resizing necessary to correct for the proximity effect in an exemplary L&S-pattern group. The data shown in FIG. 8 correspond to the L&S-pattern group shown in FIG. 6(B) projection-transferred using an electron-beam projection-lithography apparatus having an acceleration voltage of 100 kV. The horizontal axis of FIG. 8 represents the displacement of the pattern elements, as defined on the reticle, in units of μm. The displacement is measured from the center of the L&S-pattern group (regarded as having a displacement of 0 μm). The vertical axis of FIG. 8 represents the amount of local resizing necessary to correct for the proximity effect, in terms of the percentage of change required. Using an unadjusted exposure dose, the desired line-width is achieved for the apertures 10′a, 10′g, which define the edges of the L&S-pattern group (shown as having a displacement of 60 μm). At these positions, essentially no distortion is caused by the proximity effect and the amount of local resizing necessary is substantially 0%. On the other hand, for aperture 110′d, which defines a pattern element in the center of the L&S-pattern group (shown as having a displacement of 0 μm in FIG. 8), the aperture must be locally resized by about −30%.

For example, in a CPB-microlithography apparatus having a 4:1 demagnification ratio (equivalent to a demagnification factor of 1/4), a resist image having a width of 100 nm can be formed on a downstream resist by a reticle aperture having a nominal width of 400 nm (i.e., 100 nm×4=400 nm). Thus, if the reticle aperture must be resized by −30% in order to correct for the proximity effect, the aperture must be narrowed by 120 nm (i.e., 400 nm×0.3=120 nm). Accordingly, the corrected aperture on the reticle should have a width of 280 nm (i.e., 400 nm 120 nm=280 nm). Similarly, in order to obtain a resist image having a width of 70 nm, the respective aperture on the reticle has a nominal width of 280 nm (i.e., 70 nm×4=280 nm). If the same −30% proximity-effect correction is necessary, then the local-resizing correction needed is 84 nm (i.e., 280×0.3=84 nm). Thus, the corrected size of the aperture on the reticle should be about 196 nm (i.e., 280 nm −84 nm=196 nm). Finally, in order to obtain a resist image having a width of 50 nm, the respective aperture on the reticle has a nominal width of 200 nm (i.e., 50 nm×4 =200 nm). If the same −30% proximity-effect correction is necessary, then the local-resizing correction needed is 60 nm (200×0.3=60 nm). Thus, the corrected size of the aperture on the reticle should be 140 nm (i.e., 200 nm−60 nm=140 nm).

In general, the method of “negative local resizing” involves using an unadjusted exposure dose so that areas of the reticle experiencing little or no distortion caused by the proximity effect have the desired line-width, and narrowing the other apertures of the reticle expected to experience distortion. The technical burden (complexity and length of calculations) of narrowing these apertures, however, is immense. The ability to control the line-width of the resist images is therefore reduced. Moreover, the sectional aspect ratio of the reticle may be undesirably high for the corrected apertures, making production of the reticle very difficult. For instance, if a corrected aperture has a width of 140 nm and the reticle membrane has a thickness of 2 μm, then the sectional aspect ratio for the pattern element defined by the aperture will be 14 (i.e., 2000 nm−140 nm=14), which is an undesirably high value.

### SUMMARY

In view of the shortcomings of the prior art as summarized above, the present disclosure provides, inter alia, methods and apparatus for correcting the proximity effect in a charged-particle-beam (CPB) microlithography system. In general, the disclosed methods involve adjusting the exposure dose of the charged particle beam and performing local resizing on the pattern elements of a reticle in order to eliminate pattern distortions caused by the proximity effect. Reticles produced from the disclosed methods enable the formation of resist images having extremely small pattern features (e.g., line-widths of 0.1 μm or smaller).

The disclosed methods and apparatus are discussed in terms of pattern elements defined on a reticle. The reticle may be a stencil-type reticle, in which the pattern elements are defined as respective apertures in a reticle membrane, or a continuous-membrane reticle, in which pattern elements are defined by respective openings in a highly scattering layer formed on a continuous membrane.

According to a first aspect of the invention, methods termed “positive local resizing” are provided. In an embodiment of such a method, the exposure dose of a charged particle beam is adjusted so that a first pattern element of a reticle forms a first resist image having a desired line-width. In contrast to the prior art, the first pattern element is situated at a location on the reticle where distortion caused by the proximity effect is greater than average for the reticle. In one particular embodiment, the first pattern element is situated at a location on the reticle where distortion caused by the proximity effect is greatest. This location is typically an area of the reticle having a relatively high pattern-element density. A second pattern element of the reticle is then resized so that, when it is exposed to the adjusted exposure dose, the element forms a second resist image having a second desired line-width. Resizing of the second pattern element typically involves widening the pattern element on the reticle. Accordingly, the technical burdens associated with conventional methods of “negative local resizing,” which require that the pattern elements of the reticle be narrowed, are eliminated.

According to a second aspect of the invention, methods for minimizing the overall amount of local resizing necessary are provided. In an embodiment of such a method, the exposure dose of a charged particle beam is adjusted so that a first pattern element defined on a reticle forms a first resist image having a desired line-width. The first pattern element is situated at a location on the reticle where distortion caused by the proximity effect is nearly average or average for the reticle. A second pattern element of the reticle is then resized so that, when it is exposed to the adjusted exposure dose, it forms a second resist image having a second desired line-width. A third pattern element of the reticle also may be resized so that it produces a third resist image having a third desired line-width. For example, in one embodiment, the second pattern element is widened and the third pattern element is narrowed. Thus, both positive and negative local resizing are utilized to achieve the desired line-widths of the respective elements as exposed on the resist. By utilizing both positive and negative local resizing to correct for the proximity effect, the overall degree of resizing necessary can be minimized.

According to a third aspect of the invention, reticles produced from the disclosed methods are provided.

According to a fourth aspect of the invention, microelectronic devices manufactured using the methods or reticles described above are provided.

The foregoing and additional features and advantages of the invention will be more readily apparent from the following detailed description, which proceeds with reference to the accompanying drawings.

### BRIEF DESCRIPTION OF THE DRAWINGS

FIG. 1(A) is a schematic elevational diagram showing an uncorrected reticle and its corresponding resist images.

FIG. 1(B) is a schematic elevational diagram showing the reticle of FIG. 1(A) corrected according to the first representative embodiment, and the corresponding resist images of the corrected reticle.

FIG. 2 is a graph illustrating the amount of local resizing necessary to correct for the proximity effect in an exemplary L&S-pattern group, the resizing being performed according to the method of the first representative embodiment.

FIG. 3 is an elevational schematic diagram of imaging relationships and control systems of a CPB-microlithography apparatus employing a divided reticle corrected as described herein.

FIG. 4(A) is a schematic elevational diagram showing an uncorrected reticle and its corresponding resist images.

FIG. 4(B) is a schematic elevational diagram showing the reticle of FIG. 4(A) corrected according to the second representative embodiment, and the corresponding resist images of the corrected reticle.

FIG. 5 is a flowchart of steps in a process for manufacturing a microelectronic device using a reticle designed according to the disclosed methods.

FIG. 6(A) is a schematic elevational diagram showing an uncorrected reticle and its corresponding resist images.

FIG. 6(B) is a schematic elevational diagram showing the reticle of FIG. 6(A) corrected according to a conventional method for performing negative local resizing, and the corresponding resist images of the corrected reticle.

FIG. 7 is a graph showing the conventional line-width distribution of uncorrected pattern elements in an exemplary L&S-pattern group exposed using an electron-beam microlithography apparatus.

FIG. 8 is a graph illustrating the amount of local resizing that conventionally is necessary to correct for the proximity effect in an exemplary L&S-pattern group, the resizing being performed according to the conventional method of negative local resizing.

### DETAILED DESCRIPTION

This invention is described below in connection with representative embodiments that are not intended to be limiting in any way. Although the various embodiments are described as utilizing an electron beam as an exemplary charged particle beam, the general principles set forth herein are applicable with equal facility to the use of an alternative charged particle beam such as an ion beam. Furthermore, although the reticles disclosed herein are all stencil-type reticles, the principles disclosed may be applied to other types of reticles used in CPB microlithography, such as continuous-membrane (scattering-membrane) reticles. Additionally, although the reticles described below are shown as undivided reticles, the reticles typically are divided into multiple subfields, each defining a respective set of pattern elements. Finally, the reticles and resist images described below are shown as having a demagnification ratio of 1:1. It is understood, however, that the 1:1 -demagnification ratio is used for illustrative purposes only. The actual demagnification ratio used during pattern transfer may be much greater (e.g., 4:1).

General Considerations

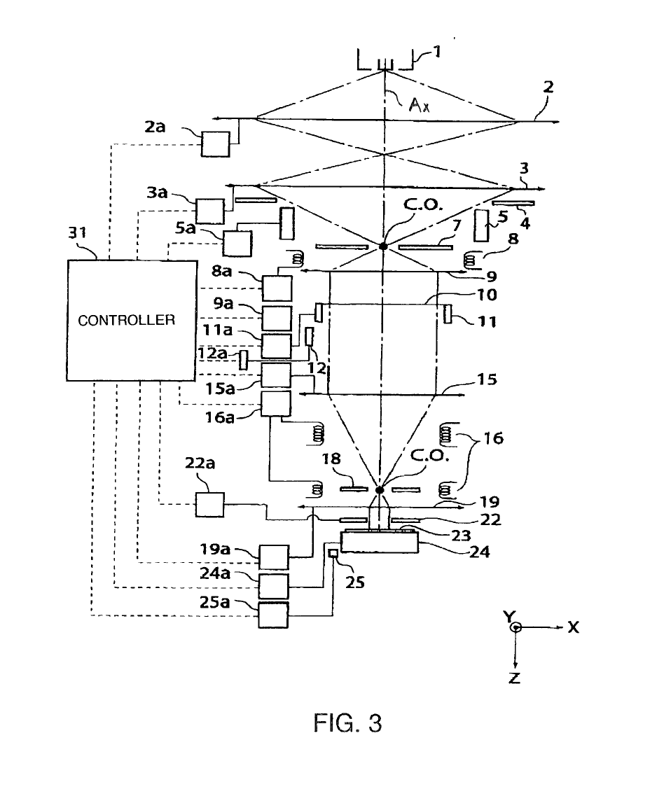

FIG. 3 shows an overview of a CPB divided-reticle projection-microlithography system. Situated at the extreme upstream end of the system is an electron gun 1 that emits an electron beam propagating in a downstream direction generally along an optical axis Ax. Downstream of the electron gun 1 are a first condenser lens 2 and a second condenser lens 3 collectively constituting a two-stage condenser-lens assembly. The condenser lenses 2, 3 converge the electron beam at a crossover C.O. situated on the optical axis Ax at a blanking diaphragm 7.

Downstream of the second condenser lens 3 is a “beam-shaping diaphragm” 4 comprising a plate defining an axial aperture (typically rectangular in profile) that trims and shapes the electron beam passing through the aperture. The aperture is sized and configured to trim the electron beam sufficiently to illuminate one exposure unit (e.g., a “subfield”) on the divided reticle 10. An image of the beam-shaping diaphragm 4 is formed on the reticle 10 by an illumination lens 9.

The electron-optical components situated between the electron gun 1 and the reticle 10 collectively constitute an “illumination-optical system” of the depicted microlithography system. The electron beam propagating through the illumination-optical system is termed an “illumination beam” because it illuminates a desired region of the reticle 10. As the illumination beam propagates through the illumination-optical system, the beam actually travels in a downstream direction through an axially aligned “beam tube” (not shown but well understood in the art) that can be evacuated to a desired vacuum level.

A blanking deflector 5 is situated downstream of the beam-shaping diaphragm 4. The blanking deflector 5 laterally deflects the illumination beam as required to cause the illumination beam to strike the aperture plate of the blanking diaphragm 7, thereby preventing the illumination beam from being incident on the reticle 10.

A subfield-selection deflector 8 is situated downstream of the blanking diaphragm 7. The subfield-selection deflector 8 laterally deflects the illumination beam as required to illuminate a desired exposure unit situated on the reticle within the optical field of the illumination optical system. Thus, exposure units of the reticle 10 are scanned sequentially by the illumination beam in a horizontal direction (X direction in the figure). The illumination lens 9, which forms the image of the beam-shaping diaphragm 4 on the reticle 10, is situated downstream of the subfield-selection deflector 8.

The divided reticle 10 typically defines many exposure units (e.g., tens of thousands of subfields) and may be manufactured using any of the methods discussed below. The exposure units collectively define the pattern for a layer to be formed at a single die (“chip”) on a lithographic substrate. The reticle 10 is mounted on a movable reticle stage 11. Using the reticle stage 11, by moving the reticle 10 in a direction (Y and/or X direction) perpendicular to the optical axis Ax, it is possible to illuminate the respective exposure units on the reticle 10 extending over a range that is wider than the optical field of the illumination-optical system. The position of the reticle stage 11 in the XY plane is determined using a “position detector” 12 typically configured as a laser interferometer. The laser interferometer is capable of measuring the position of the reticle stage 11 with extremely high accuracy in real time.

Situated downstream of the reticle 10 are first and second projection lenses 15, 19, respectively, and an imaging-position deflector 16. The illumination beam, by passage through an illuminated exposure unit of the reticle 10, becomes a “patterned beam” because the beam has acquired an aerial image of the illuminated subfield. The patterned beam is imaged at a specified location on a substrate 23 (e.g., “wafer”) by the projection lenses 15, 19 collectively functioning as a “projection-lens assembly.” To ensure imaging at the proper location, the imaging-position deflector 16 imparts the required lateral deflection of the patterned beam.

So as to be imprintable with the image carried by the patterned beam, the upstream-facing surface of the substrate 23 is coated with a suitable “resist” that is imprintably sensitive to exposure by the patterned beam. When forming the image on the substrate, the projection-lens assembly “reduces” (demagnifies) the aerial image. Thus, the image as formed on the substrate 23 is smaller (usually by a defined integer-ratio factor termed the “demagnification factor”) than the corresponding region illuminated on the reticle 10. By thus causing imprinting on the surface of the substrate 23, the apparatus of FIG. 3 achieves “transfer” of the pattern image from the reticle 10 to the substrate 23.

The components of the depicted electron-optical system situated between the reticle 10 and the substrate 23 are collectively termed the “projection-optical system.” The substrate 23 is situated on a substrate stage 24 situated downstream of the projection-optical system. As the patterned beam propagates through the projection-optical system, the beam actually travels in a downstream direction through an axially aligned “beam tube” (not shown but well understood in the art) that can be evacuated to a desired vacuum level.

The projection-optical system forms a crossover C.O. of the patterned beam on the optical axis Ax at the rear focal plane of the first projection lens 15. The position of the crossover C.O. on the optical axis Ax is a point at which the axial distance between the reticle 10 and substrate 23 is divided according to the demagnification factor. Situated between the crossover C.O. (i.e., the rear focal plane) and the reticle 10 is a contrast-aperture diaphragm 18. The contrast-aperture diaphragm 18 comprises an aperture plate that defines an aperture. With the contrast-aperture diaphragm 18, electrons of the patterned beam that were scattered during transmission through the reticle 10 are blocked so as not to reach the substrate 23.

A backscattered-electron (BSE) detector 22 is situated immediately upstream of the substrate 23. The BSE detector 22 is configured to detect and quantify electrons backscattered from certain marks situated on the upstream-facing surface of the substrate 23 or on an upstream-facing surface of the substrate stage 24. For example, a mark on the substrate 23 can be scanned by a beam that has passed through a corresponding mark pattern on the reticle 10. By detecting backscattered electrons from the mark at the substrate 23, it is possible to determine the relative positional relationship of the reticle 10 and the substrate 23.

The substrate 23 is mounted to the substrate stage 24 via a wafer chuck (not shown but well understood in the art), which presents the upstream-facing surface of the substrate 23 in an XY plane. The substrate stage 24 (with chuck and substrate 23) is movable in the X and Y directions. Thus, by simultaneously scanning the reticle stage 11 and the substrate stage 24 in mutually opposite directions, it is possible to transfer each exposure unit within the optical field of the illumination-optical system as well as each exposure unit outside the optical field to corresponding regions on the substrate 23. The substrate stage 24 also includes a “position detector” 25 configured similarly to the position detector 12 of the reticle stage 11.

Each of the lenses 2, 3, 9, 15, 19 and deflectors 5, 8, 16 is controlled by a controller 31 via a respective coil-power controller 2a, 3a, 9a, 15a, 19a and 5a, 8a, 16a. Similarly, the reticle stage 11 and substrate stage 24 are controlled by the controller 31 via respective stage drivers 11 a, 24a. The position detectors 12, 25 produce and route respective stage-position signals to the controller 31 via respective interfaces 12a, 25a each including amplifiers, analog-to-digital (A/D) converters, and other circuitry for achieving such ends. In addition, the BSE detector 22 produces and routes signals to the controller 31 via a respective interface 22a.

From the respective data routed to it, the controller 31 ascertains, inter alia, any control errors of the respective stage positions as a subfield is being transferred. To correct such control errors, the imaging-position deflector 16 is energized appropriately to deflect the patterned beam. Thus, a reduced image of the illuminated exposure unit on the reticle 10 is transferred accurately to the desired target position on the substrate 23. This real-time correction is made as each respective image of an exposure unit is transferred to the substrate 23, and the images are positioned such that they are stitched together properly on the substrate 23.

First Representative Embodiment

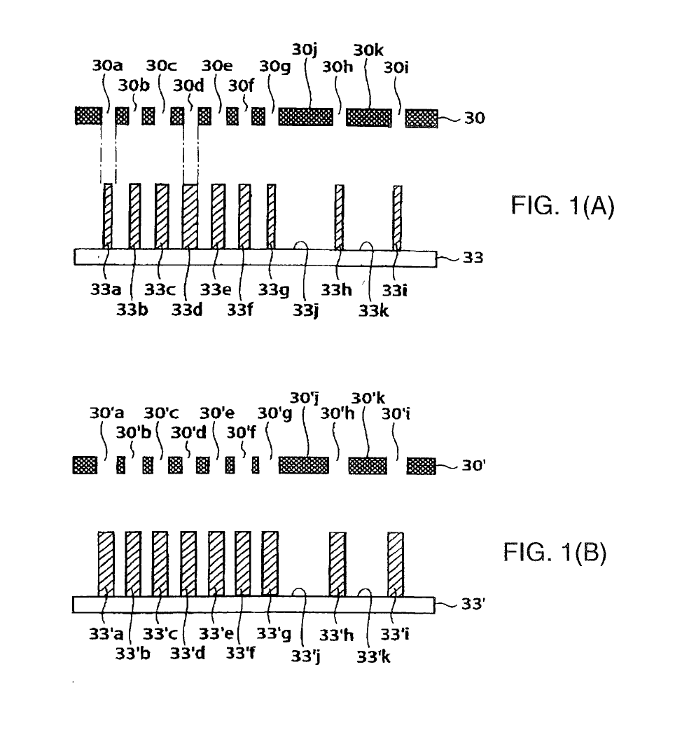

FIGS. 1(A)-1(B) illustrate the proximity-effect-correction method according to a first representative embodiment. In this embodiment, the exposure dose is adjusted so that the desired line-width is obtained for pattern elements located in areas of the reticle where the proximity effect is greater than average (i.e., where the amount of backscattered electrons is larger than average for the reticle being exposed). In one particular embodiment, the exposure dose is adjusted so that the desired line-width is obtained for areas of the reticle where the proximity effect is greatest. The apertures defining the other pattern elements are then resized (positively resized) by the necessary amount in order to correct for the proximity effect.

In FIG. 1(A), a stencil-type reticle 30 defines multiple apertures 30a-30i, which form various respective pattern elements of the pattern being transferred. The apertures 30a-30g correspond to pattern elements in a dense L&S-pattern group, whereas the apertures 30h, 30i correspond to pattern elements separated from one another by wide solid regions 30j, 30k. In FIG. 1(A), the widths of the apertures 30a-30i are identical. A wafer 33 is located downstream of the reticle 30. Negative resist images 33a-33i are formed on the wafer 33 after exposure to an electron beam shaped by the apertures 30a-30i, respectively. Spaces 33j, 33k correspond to the solid regions 30j, 30k, respectively.

In FIG. 1(A), the resist image 33d is located in the center of the L&S-pattern group 33a-33g. The resist image 33d is formed by the electron beam passing through the aperture 30d. In the illustrated embodiment, the exposure dose is adjusted such that the resist image 33d has, due to the proximity effect caused by the density of pattern elements surrounding it, the desired line-width. By contrast, the other resist images in the group 33a-33g have narrower line-widths. In particular, the resist images 33a, 33g have the narrowest line-widths because the proximity effect is smallest at the ends of the L&S-pattern group 33a-33g. Similarly, the resist images 33h, 33i are narrower than the desired pattern width because they are formed by the electron beam passing through the apertures 30h, 30i, respectively, which are located in an area of the reticle in which little or no distortion is caused by the proximity effect.

FIG. 1(B) shows a stencil-type reticle 30′ defining multiple corrected apertures 30′a-30′i that have been locally resized in accordance with the method of the first representative embodiment. As in FIG. 1(A), FIG. 1(B) shows a group of apertures 30′a-30′g corresponding to respective pattern elements in a dense L&S-pattern group. Other apertures 30′h, 30′i correspond to respective pattern elements separated from one another by wide solid regions 30′j, 30′k. The width of the corrected aperture 30′d is nearly the same as of the uncorrected aperture 30d shown in FIG. 1(A). In other words, almost no local resizing was performed on the aperture 30d in FIG. 1(A) to form the aperture 30′d in FIG. 1(B). By contrast, the apertures 30h, 30i, 30a, and 30g are wider in FIG. 1(B) than in FIG. 1(A) by respective amounts necessary to correct for the proximity effect. It is understood that the degree of widening shown in FIG. 1(B) is for illustrative purposes only and may not reflect the actual degree of widening necessary.

A wafer 33′ is located downstream of the reticle 30′. Negative resist images 33′a-33′i are formed on the wafer 33′ after exposure to an electron beam shaped by the apertures 30′a-30′i, respectively. Spaces 33j, 33′k are formed downstream of the solid regions 30′j, 30′k, respectively. By widening the apertures to compensate for the proximity effect, the resist images 33′a, 33′g, which are positioned at respective ends of the L&S-pattern group 33′a-33′g, can be formed with the desired line-width. Similarly, the resist images 33′h, 33′i, which are located in an area of the reticle in which little or no distortion occurs from the proximity effect, can be formed with the desired line-width.

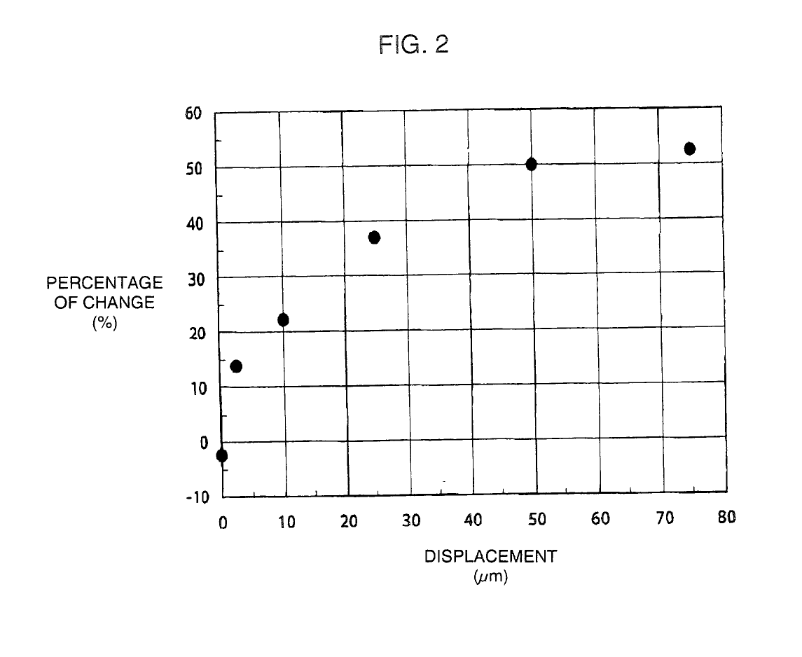

FIG. 2 is a graph illustrating the amount of local resizing necessary to correct for the proximity effect in the exemplary L&S-pattern group shown in FIGS. 1(A)-1(B). The data shown in FIG. 2 correspond to the L&S-pattern group shown in FIGS. 1(A)-1(B) and were obtained using an electron-beam projection-lithography apparatus having an acceleration voltage of 100 kV. The horizontal axis of FIG. 2 represents the displacement of the pattern element formed on the reticle in units of micrometers (μm). The displacement is measured from the center of the L&S-pattern group (shown as having a displacement of 0 μm). The vertical axis of FIG. 2 represents the amount of resizing in terms of the percentage of change necessary for correcting the proximity effect. In this example, the exposure dose is adjusted such that the desired line-width is achieved for the aperture defining the pattern element in the center of the L&S pattern group (i.e., the aperture 30′d in FIG. 1(B)). Thus, the amount of local resizing necessary at this position is nearly 0%. On the other hand, for the apertures 10′a, 10′g, which define pattern elements at the respective ends of the L&S-pattern group (shown in FIG. 2 as having a displacement of 50 μm), the apertures must be locally resized by about 50%.

For example, in a CPB-microlithography apparatus having a 4:1 demagnification ratio, a resist image having a width of 100 nm can be formed on a wafer by a reticle aperture having a nominal width of 400 nm. Thus, if the reticle aperture must be locally resized by 50% in order to correct for the proximity effect, the aperture must be widened by 200 nm (i.e., 400 nm×0.5×200 nm). Accordingly, the corrected aperture has a width of 600 nm (i.e., 400 nm+200 nm=600 nm). Similarly, in order to obtain a resist image having a width of 70 nm on the wafer, the aperture on the reticle nominally is 280 nm (i.e., 70 nm×4=280 nm). If the same 50% proximity effect correction is necessary, then the local-resizing correction needed is 140 nm (i.e., 280×0.5=140 nm). Thus, the width of the corrected aperture on the reticle is 420 nm (i.e., 280 nm+140 nm=420 nm). Finally, to obtain a resist image having a width of 50 nm, the aperture on the reticle has a nominal width of 200 nm (i.e., 50 nm×4=200 nm). If the same 50% proximity-effect correction is necessary, then the local-resizing correction needed is 100 nm (i.e., 200 nm×0.5=100 nm). Thus, the width of the corrected aperture on the reticle is 300 nm (i.e., 200 nm+100 nm=300 nm).

Accordingly, if the exposure dose is adjusted such that areas of the reticle experiencing the greatest distortion (or greater than average distortion) caused by the proximity effect have the desired line-width, then other apertures of the reticle (or apertures experiencing less than average distortion) can be widened to correct for the proximity effect. Thus, the technical burdens that resulted from the prior art technique of narrowing the reticle apertures are avoided.

Second Representative Embodiment

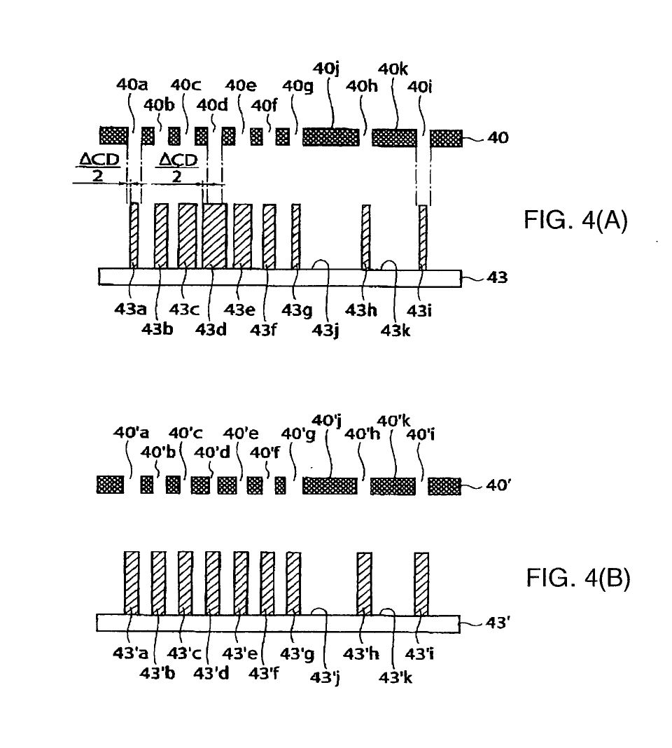

FIGS. 4(A)-4(B) illustrate a proximity-effect-correction method according to the second representative embodiment. In this embodiment, the exposure dose is adjusted so that the desired line-width is obtained for pattern elements located in areas of the reticle where the proximity effect is nearly average or average (i.e., where the amount of backscattered electrons is nearly average or average for the reticle being exposed). The apertures defining other respective pattern elements are locally resized (both positively and negatively) by the necessary amount in order to correct for the proximity effect.

In FIG. 4(A), a stencil-type reticle 40 defines multiple apertures 40a-40i, which form various respective pattern elements of the pattern being transferred. The apertures 40a-40g correspond to respective pattern elements in a dense L&S-pattern group, whereas the apertures 40h, 40i correspond to respective pattern elements separated from one another by wide solid regions 40j, 40k. In FIG. 4(A), the widths of the apertures 40a-40i are identical. A wafer 43 is located downstream of the reticle 40. Negative resist images 43a-43i are formed on the wafer 43 after exposure to an electron beam shaped by the apertures 40a-40i, respectively. Spaces 43j, 43k are formed downstream of the solid regions 40j, 40k, respectively.

In the illustrated embodiment, the resist images 43b, 43f, which are formed by the electron beam passing through the apertures 40b, 40f, respectively, have the desired pattern width. By contrast, the resist image 43d, which is located in the center of the L&S-pattern group 43a-43g, is wider than the desired line-width because of the proximity effect. Similarly, the resist images 43a, 43g, which are located at the ends of the L&S-pattern group 43a-43g, are narrower than the desired line-width because of the proximity effect. The resist images 43h, 43i are also narrower than the desired line-width because they are formed by the apertures 40h, 40i, respectively, which are located in an area of the reticle exhibiting little or no distortion caused by the proximity effect. In FIG. 4(A), the difference between the desired line-width and the actual line-width is labeled “ΔCD,” and half the difference is labeled “ACD/2”.

FIG. 4(B) shows a stencil-type reticle 40′ defining multiple corrected apertures 40′a-40′i that have been locally resized (both positively and negatively) in accordance with the method of the second representative embodiment. FIG. 4(B) shows a group of apertures 40′a-40′g corresponding to respective pattern elements in a dense L&S-pattern group and apertures 40′h, 40′i corresponding to respective pattern elements separated from one another by wide solid regions 40′j, 40′k. The width of the corrected apertures 40′b, 40′f is nearly the same as the uncorrected apertures 40b, 40f shown in FIG. 4(A). In other words, almost no local resizing was performed on the apertures 40b, 40f in FIG. 4(A) to form the apertures 40′b, 40′f in FIG. 4(B). By contrast, the aperture 40′d, which is located at the center of the group 40′a-40′g, is narrower than the aperture 40d by an amount necessary to correct for the proximity effect. Conversely, the apertures 40h, 40i, 40a, and 40g are wider in FIG. 4(B) than in FIG. 4(A) by respective amounts calculated to correct for the proximity effect. It is understood that the degree of narrowing and widening shown in FIG. 4(B) is for illustrative purposes only and may not reflect the actual degree of local resizing necessary.

A wafer 43′ is located downstream of the reticle 40′. Negative resist images 43′a-43′i are formed on the wafer 43′ after exposure to an electron beam shaped by the apertures 40′a-40′i, respectively. Spaces 43′j, 43′k are formed downstream of the solid regions 40′j, 40′k, respectively. As shown in FIG. 4(B), the corrected apertures 40′a-40′i allow all the resist images 43′a-43′i to have the desired line-width.

By adjusting the exposure dose such that no local resizing is necessary for apertures exhibiting average levels of distortion due to the proximity effect, the degree to which the apertures must be locally resized is minimized. For instance, the apertures may need to be locally resized by +15-20%. This amount is significantly less than the amount of local resizing required by the prior art method. Additionally, local resizing of the apertures can be performed more efficiently, even in cases where the aperture dimensions do not change greatly.

Third Representative Embodiment

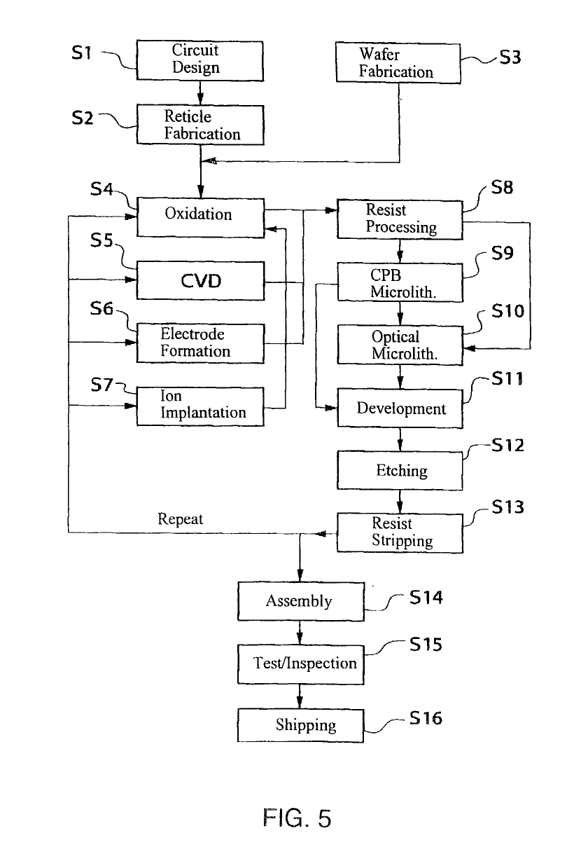

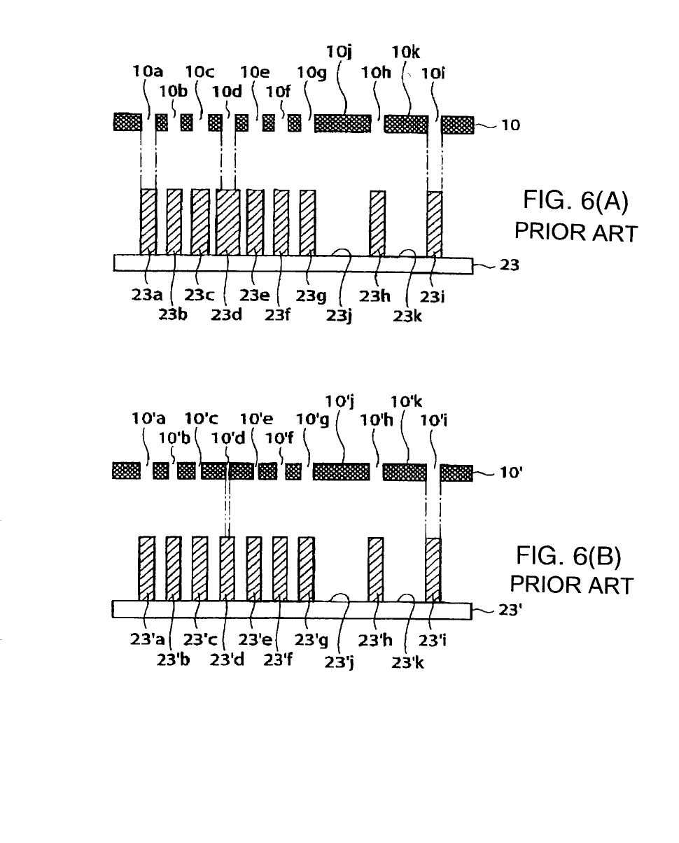

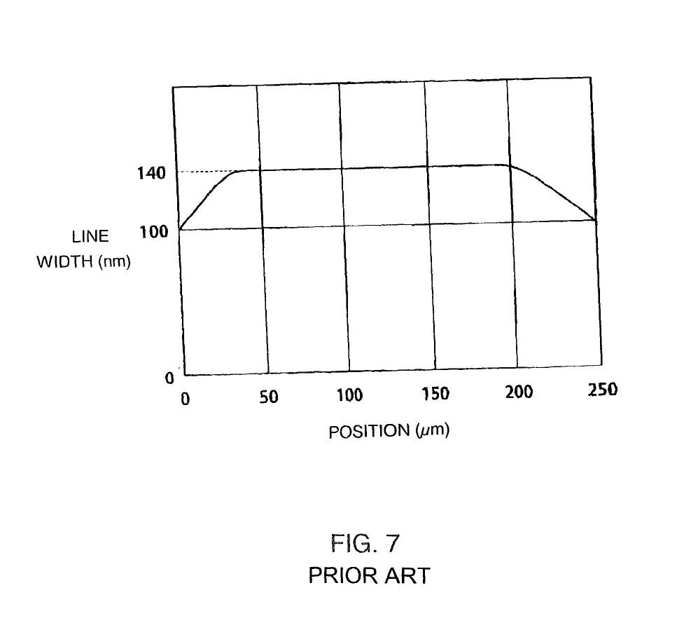

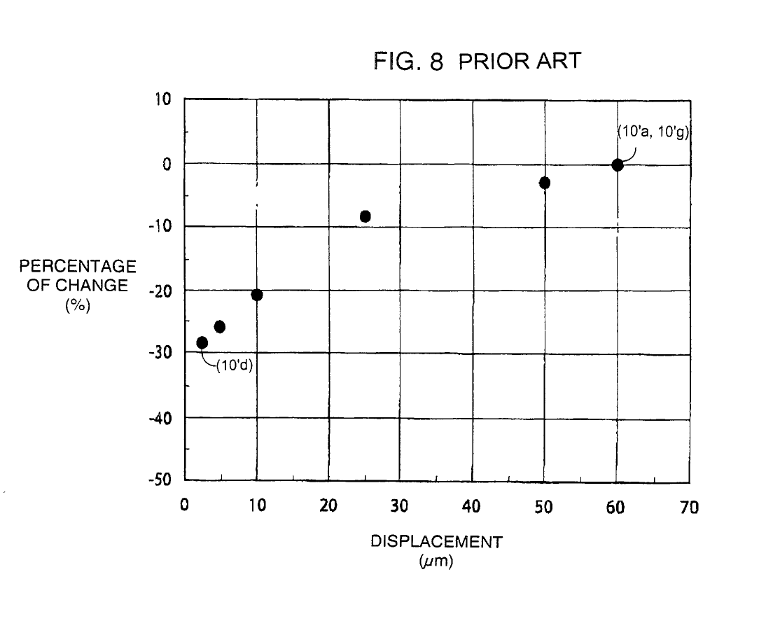

FIG. 5 is a flow chart of steps in a process for manufacturing a microelectronic device such as a semiconductor chip (e.g., an integrated circuit or LSI device), a display panel (e.g., liquid-crystal panel), charge-coupled device (CCD), thin-film magnetic head, micromachine, for example. In step S1, the circuit for the device is designed. In step S2 a reticle (“mask”) for the circuit is manufactured. In step S2, the local resizing techniques described above can be performed in order to correct for the proximity effect during exposure. In step S3, a wafer is manufactured from a material such as silicon.

Steps S4-S13 are directed to wafer-processing steps, in which the circuit pattern defined on the reticle is transferred onto the wafer by microlithography. Step S14 is an assembly step (also termed a “post-process” step) in which the wafer that has been passed through steps S4-S13 is formed into semiconductor chips. This step can include, e.g., assembling the devices (dicing and bonding) and packaging (encapsulation of individual chips). Step S15 is an inspection step in which any of various operability and qualification tests of the device produced in step S14 are conducted. Afterward, devices that successfully pass step S15 are finished, packaged, and shipped (step S16).

Steps S4-S13 also provide representative details of wafer processing. Step S4 is an oxidation step for oxidizing the surface of a wafer. Step S5 involves chemical vapor deposition (CVD) for forming an insulating film on the wafer surface. Step S6 is an electrode-forming step for forming electrodes on the wafer (typically by vapor deposition). Step S7 is an ion-implantation step for implanting ions (e.g., dopant ions) into the wafer. Step S8 involves application of a resist (exposure-sensitive material) to the wafer. Step S9 involves microlithographically exposing the resist using a CPB-microlithography apparatus, such as an electron-beam-microlithography apparatus, and using the reticle made in step S2. Step S10 involves microlithographically exposing the resist using optical microlithography. This step can also be performed using the reticle produced in step S2. Step S11 involves developing the exposed resist on the wafer. Step S12 involves etching the wafer to remove material from areas where developed resist is absent. Step S13 involves resist separation, in which remaining resist on the wafer is removed after the etching step. By repeating steps S4-S13 as required, circuit patterns as defined by successive reticles are formed superposedly on the wafer.

Working Example

The following example is provided to exemplify certain features of the disclosed embodiments of the described method. The scope of the invention should not be limited those features exemplified.

In the experiment, the proximity-effect-correction methods described above were used to prepare reticles for use in an electron-beam microlithography apparatus. The reticles used in the experiment comprised 2-mm-thick electron-scattering membranes (or substrates). The membranes were made of silicon and were supported by a strut structure. The membranes were formed on the reticles using a 6-inch silicon-on-insulator (SOI) wafer. In order to control the positional strain experienced in the membranes, the SOI wafers were thermally diffused with boron. Before being corrected for the proximity effect, the reticles defined a gate pattern having a line-width of 400 nm and a line-to-space ratio of 1:1. In order to simplify the pattern, the circuit at the periphery of the gate was omitted from the reticle patterns.

The microlithography apparatus used during exposure was an electron-beam stepper developed by Nikon Corp. The electron beam of the apparatus had an acceleration voltage of 100 kV, a demagnification ratio of 4:1, an exposure area of 0.25 mm×0.25 mm, and a maximum exposure dose of about 30 mC/cm². The exposed substrate comprised an 8-inch silicon wafer. The silicon wafer was coated with a 0.3-mm-thick resist layer, which was prebaked onto the wafer. The resist layer was a chemically amplified negative resist from the NEB series developed by Sumitomo Chemical Inc.

Two reticles were prepared for the experiment. The first reticle was prepared utilizing the proximity-effect-correction method according to the first representative embodiment described above. Thus, many of the apertures of the reticle were enlarged in order to correct for the proximity effect (positive local resizing). The second reticle was prepared utilizing the proximity-effect-correction method according to the second representative embodiment described above. Thus, many of the apertures of the reticle were either widened or narrowed, and the overall amount of local resizing necessary was minimized. The respective correction values were calculated using data-transformation software.

For the uncorrected reticle, the maximum amount of line-width deformation resulting from the 30 mC/cm² exposure dose was calculated to be 115 nm (an increase in line-width of 28.75%). After performing positive local resizing on the first reticle according to the first representative embodiment described above, the optimal exposure dose was found to be 26.45 mC/cm². At this exposure dose and after the appropriate local resizing was performed, the desired gate pattern having a line-width of 100 nm was formed in the resist. Similarly, after minimizing the overall amount of local resizing necessary on the second reticle according to the second representative embodiment described above, the optimal exposure dose was found to be 28.7 mC/cm². At this exposure dose and after the appropriate local resizing was performed, the desired gate pattern having a line-width of 100 nm was formed in the resist.

Whereas the invention has been described in connection with multiple representative embodiments, it will be understood that the invention is not limited to those embodiments. On the contrary, the invention is intended to encompass all modifications, alternatives, and equivalents as may be included within the spirit and scope of the invention, as defined by the appended claims.

What is claimed is:

1. A method for correcting a proximity effect in a microlithography-exposure apparatus utilizing a charged particle beam, comprising:
adjusting an exposure dose of the charged particle beam so that a first pattern element of a reticle forms a first resist image having a first desired line-width, the pattern element being situated at a location on the reticle where distortion caused by the proximity effect is greater than average for the reticle; and
resizing a second pattern element of the reticle so that the second pattern element forms a second resist image having a second desired line-width when exposed at the adjusted exposure dose.

2. The method of claim 1, wherein the resizing comprises calculating a local-resizing correction for the second pattern element.

3. The method of claim 1, wherein the resizing comprises widening the second pattern element of the reticle relative to a nominal width for the second pattern element.

4. The method of claim 1, wherein the location on the reticle is a location where distortion caused by the proximity effect is greatest for the reticle.

5. The method of claim 1, wherein the location on the reticle is an area of the reticle having a relatively high pattern-element density.

6. The method of claim 1, wherein the reticle is a subfield of a divided reticle.

7. The method of claim 1, wherein the reticle is a stencil-type reticle, and the first and second pattern elements are first and second apertures.

8. A method for correcting a proximity effect in a microlithography-exposure apparatus utilizing a charged particle beam, comprising:
adjusting an exposure dose of the charged particle beam so that a first pattern element of a reticle forms a first resist image having a first desired line-width, the first pattern element being situated in a location on the reticle where distortion caused by the proximity effect is nearly average for the reticle; and
resizing a second pattern element of the reticle so that the second pattern element forms a second resist image having a second desired line-width when exposed at the adjusted exposure dose.

9. The method of claim 8, wherein the resizing comprises calculating a local-resizing correction for the second pattern element.

10. The method of claim 8, wherein the resizing comprises widening the second pattern element of the reticle relative to a nominal width for the second pattern element, the method further comprising resizing a third pattern element of the reticle by narrowing the third pattern element, relative to a nominal width for the third pattern element, so that the third pattern element forms a third resist image having a third desired line-width when exposed to the adjusted exposure dose of the charged particle beam.

11. The method of claim 8, wherein the location on the reticle is a location where distortion caused by the proximity effect is average for the reticle.

12. The method of claim 8, wherein the reticle is a subfield of a divided reticle.

13. The method of claim 8, wherein the reticle is a stencil-type reticle, and the first and second pattern elements are first and second apertures.

14. A reticle produced according to the method of claim 1.

15. A reticle produced according to the method of claim 8.

16. A reticle defining a pattern to be transferred onto a specific area of a sensitive substrate, comprising:
a reticle membrane; and
a pattern defined on the reticle membrane, the pattern including a pattern element that is locally resized such that the pattern element is larger than an original design size for the pattern element, the pattern element being situated in a location on the reticle membrane where distortion caused by a proximity effect is less than average for the reticle.

17. The reticle of claim 16, wherein the location on the reticle membrane has a relatively low pattern-element density.

18. The reticle of claim 16, wherein the reticle is a stencil-type reticle, and the pattern element is an aperture.

19. The reticle of claim 16, wherein the reticle is a subfield of a divided reticle.

20. The reticle of claim 16, wherein the pattern element is a first pattern element, and the area of the reticle membrane is a first area, the pattern further comprising a second pattern element situated in a second location on the reticle membrane where distortion caused by the proximity effect is greater than average for the reticle, the second pattern element being used to adjust an exposure dose such that the second pattern element creates a resist image having a desired line-width.

21. The reticle of claim 20, wherein the second location on the reticle membrane is an area where distortion caused by the proximity effect is greatest for the reticle.

22. A reticle defining a pattern to be transferred onto a specific area of a sensitive substrate, comprising:
a reticle membrane; and
a pattern defined on the reticle membrane,
the pattern including a first pattern element that is locally resized such that the first pattern element is larger than a respective original design size for the first pattern element, the first pattern element being situated in a first location on the reticle membrane where distortion caused by the proximity effect is less than average for the reticle,
the pattern further including a second pattern element that is locally resized such that the second pattern element is smaller than a respective original design size for the second pattern element, the second pattern element being situated in a second location on the reticle membrane where distortion caused by the proximity effect is greater than average for the reticle.

23. The reticle of claim 22, wherein the reticle is a stencil-type reticle, and the first and second pattern elements are first and second apertures.

24. The reticle of claim 22, wherein the reticle is a subfield of a divided reticle.

25. The reticle of claim 22, wherein the pattern further comprises a third pattern element situated in a location on the reticle membrane where distortion caused by the proximity effect is average for the reticle, the third pattern element being used to adjust an exposure dose such that the third pattern element creates a resist image having a desired line-width.

26. The reticle of claim 25, wherein the first location on the reticle membrane has a relatively low pattern-element density and the second location on the reticle membrane has a relatively high pattern-element density.

27. A method for manufacturing a reticle for use in a charged-particle-beam-microlithography apparatus, comprising:
defining a pattern having multiple pattern elements having respective nominal line-widths;
determining an exposure dose of the charged particle beam at which a first pattern element of the pattern forms a respective resist image having a respective desired line-width, the first pattern element being situated at a location on the pattern where distortion caused by the proximity effect is greater than average for the pattern;
increasing the line-width of a second pattern element of the pattern, relative to its respective nominal line-width, to create a corrected second pattern element, the corrected second pattern element forming a respective resist image having a respective desired line-width when exposed at the determined exposure dose; and
fabricating the reticle, the reticle defining a corrected pattern including the first pattern element and the corrected second pattern element.

28. The method of claim 27, wherein the location on the pattern is a location where distortion caused by the proximity effect is greatest for the pattern.

29. The method of claim 27, wherein the reticle is a divided reticle comprising multiple subfields.

30. The method of claim 27, wherein the reticle is a stencil-type reticle, and the first pattern element and the corrected second pattern element are respective apertures in a membrane of the reticle.

31. A reticle manufactured by the method of claim 27.

32. A method for manufacturing a reticle for use in a charged-particle-beam-microlithography apparatus, comprising:
defining a pattern having multiple pattern elements each having a respective nominal line-width;
determining an exposure dose of the charged particle beam at which a first pattern element of the pattern forms a respective resist image having a respective desired line-width, the first pattern element being situated at a location on the pattern where distortion caused by the proximity effect is substantially average for the pattern;
increasing the line-width of a second pattern element of the pattern to create a corrected second pattern element, the corrected second pattern element forming a respective resist image having a respective desired line-width when exposed at the determined exposure dose;
reducing the line-width of a third pattern element of the pattern to create a corrected third pattern element, the corrected third pattern element forming a respective resist image having a respective desired line-width when exposed at the determined exposure dose; and
fabricating the reticle, the reticle defining a corrected pattern including the first pattern element and the corrected second and third pattern elements.

33. The method of claim 32, wherein the location on the pattern is a location where distortion caused by the proximity effect is average for the pattern.

34. The method of claim 32, wherein the reticle is a divided reticle comprising multiple subfields.

35. The method of claim 32, wherein the reticle is a stencil-type reticle, and the first pattern element and the corrected second and third pattern elements are respective apertures in a membrane of the reticle.

36. A reticle manufactured by the method of claim 32.

37. A method of transferring a pattern having multiple pattern elements to a sensitive substrate using a charged particle beam, comprising:
determining an exposure dose of the charged particle beam at which a first pattern element of the pattern forms a respective resist image having a respective desired line-width, the first pattern element being situated at a location on the pattern where distortion caused by the proximity effect is greater than average for the pattern;
increasing the line-width of a second pattern element of the pattern, relative to a respective nominal line-width for the element, to create a corrected second pattern element, the corrected second pattern element forming a respective resist image having a respective desired line-width when exposed at the determined exposure dose;
fabricating a reticle, the reticle defining a corrected pattern including the first pattern element and the corrected second pattern element; and
microlithographically transferring the corrected pattern to the sensitive substrate using the charged particle beam.

38. The method of claim 37, wherein the location on the pattern is a location where distortion caused by the proximity effect is greatest for the pattern.

39. The method of claim 37, wherein the reticle is a divided reticle comprising multiple subfields.

40. The method of claim 37, wherein the reticle is a stencil-type reticle, and the first pattern element and the corrected second pattern element are respective apertures in a membrane of the reticle.

41. A microelectronic device manufactured by the method of claim 37.

42. A method of transferring a pattern having multiple pattern elements to a sensitive substrate using a charged particle beam, comprising:
determining an exposure dose of the charged particle beam at which a first pattern element of the pattern forms a respective resist image having a respective desired line-width, the first pattern element being situated at a location on the pattern where distortion caused by the proximity effect is greater than average for the pattern;
increasing the line-width of a second pattern element of the pattern, relative to a respective nominal line-width for the element, to create a corrected second pattern element, the corrected second pattern element forming a respective resist image having a respective desired line-width when exposed at the determined exposure dose;
reducing the line-width of a third pattern element of the pattern, relative to a respective nominal line-width for the element, to create a corrected third pattern element, the corrected third pattern element forming a respective resist image having a respective desired line-width when exposed at the determined exposure dose;
fabricating a reticle, the reticle defining a corrected pattern including the first pattern element and the corrected second and third pattern elements; and
microlithographically transferring the corrected pattern to the sensitive substrate using the charged particle beam.

43. The method of claim 42, wherein the location on the pattern is a location where distortion caused by the proximity effect is average for the pattern.

44. The method of claim 42, wherein the reticle is a divided reticle comprising multiple subfields.

45. The method of claim 42, wherein the reticle is a stencil-type reticle, and the first pattern element and the corrected second and third pattern elements are respective apertures in a membrane of the reticle.

46. A microelectronic device manufactured by the method of claim 42.
